(19) United States
(12) Patent Application Publication
(10) Pub. No.: US 2013/0183774 A1
(43) Pub. Date: Jul. 18, 2013

(54) Integrated Circuit Testing Method

(71) Applicants: Raphael Paulin, Le Versoud (FR); Patrice Garcia, Crolles (FR)

(72) Inventors: Raphael Paulin, Le Versoud (FR); Patrice Garcia, Crolles (FR)

(73) Assignee: STMICROELECTRONICS SA, Montrouge (FR)

(21) Appl. No.: 13/619,583

(22) Filed: Sep. 14, 2012

(30) Foreign Application Priority Data
Jan. 17, 2012 (FR) 1250459

(51) Int. Cl. G01R 31/26; H01L 21/66; G06F 19/00

(52) U.S. Cl. 438/16; 702/58; 257/E21.531

(57) ABSTRACT

A method for testing an integrated circuit includes determining performance data of the integrated circuit, wherein at least first and second derivatives of S parameters of the integrated circuit are taken into account when determining the expected performance data. The performance data can be determined by measuring S parameters of the integrated circuit. An equivalent non-linear model of the integrated circuit can be determined from the provided S parameters and first and second derivatives of the provided S parameters. The non-linear behavior of the integrated circuit can be quantified from the equivalent non-linear model.

### CROSS-REFERENCE TO RELATED APPLICATIONS

This application claims the priority benefit of French patent application number 12/50459, filed on Jan. 17, 2012, which is hereby incorporated by reference to the maximum extent allowable by law.

### TECHNICAL FIELD

The present disclosure relates to a method for testing an integrated circuit, in some embodiments, to model its non-linear operation.

### BACKGROUND

When manufacturing a new integrated circuit, tests may be carried out to determine the behavior of the integrated circuit when it receives high-amplitude signals, also called large signals. Manufacturing of a new integrated circuit here indifferently means the design of an integrated circuit corresponding to a new electronic circuit or comprising new electronic components or the implementation of a new method for manufacturing an integrated circuit corresponding to a conventional electronic circuit.

It is generally desirable for the linear behavior of an integrated circuit to be kept for signals received by the integrated circuit having the highest possible amplitudes. For this purpose, the test method generally comprises determining parameters representative of the deviation of the integrated circuit behavior from a linear behavior. Such parameters are called non-linear behavior quantification parameters hereinafter. When the non-linearity parameters are not within desired ranges of values, it may be necessary to modify the integrated circuit.

An example of a non-linearity parameter is the 1-dB gain compression point or IP1 dB, which quantifies the non-linear operation of the circuit. In the linear area, when the input power increases, the output power increases according to a constant ratio. From a given input level, the output power becomes smaller than expected. The 1-dB gain compression point is the point for which the output power is smaller by 1 dB than the ideal theoretical power.

Another non-linearity parameter is the third order intercept point or IP3. This non-linearity parameter characterizes the integrated circuit intermodulation. A signal having its frequency spectrum comprising two fundamental lines at close frequencies is provided to the circuit. Intercept point IP3 is then obtained by determining the intersection of the theoretical straight line corresponding to the variation of the output power versus the input power for a 3rd-order intermodulation frequency. Point IP3 is the point of intersection of the two curves.

Generally, an integrated circuit manufacturer has a library of models for each electronic component capable of being used on design of a new integrated circuit. These are complex models, which enable simulation of the behavior of the electronic component in most possible operating conditions, especially in small signals and in large signals, for different integrated circuit biasing conditions and for different operating temperatures. Examples of models are the BSIM (Berkeley Short-Channel IGFET Model) or PSP (Berkeley Short-Channel IGFET Model), which are a family of models of insulated gate field effect transistors or MOS (Metal Oxide Semiconductor) transistors.

On design of a new integrated circuit, the model of each electronic component of the integrated circuit is used to simulate the integrated circuit behavior. An example of a digital simulation is the harmonic balance method, which especially enables to study the distortion phenomena which may occur when the integrated circuit receives a signal comprising several frequencies and having an amplitude corresponding to a large signal behavior. Such digital simulation methods enable to determine the non-linear behavior quantification parameters.

However, the design of a new integrated circuit may require the design of a new electronic component. The integrated circuit manufacturer then may not have the complex model for this new electronic component. Similarly, the modification of an integrated circuit manufacturing method may result in the impossibility of using complex models used up to then to simulate the integrated circuit behavior.

Determining a new complex electronic component model is a long and complicated process. As an example, model BSIM4.4 of the BSIM model family for a MOS transistor requires determining more than 302 parameters. As an example, model PSP103.1 of the PSP model family for a MOS transistor requires determining more than 319 parameters.

Further, developing a new integrated circuit may require several successive integrated circuit manufacturing and testing iterations. It may be impossible, for reasons of time and cost, to design new complex electronic component modes for each attempt.

Another possibility is, when the integrated circuit is manufactured, to measure the non-linear behavior quantification parameters by integrated circuit testing methods which are supposed to correspond to an experimental simulation of the excitation conditions likely to be imposed to the integrated circuit according to the targeted application.

An example of an experimental simulation testing method is known as the “Load-Pull” method and comprises presenting the integrated circuit with different source and load (or input and output) impedances and measuring its power behavior, for an input signal having a frequency spectrum comprising two lines at close frequencies, and a given bias point.

In particular, for an integrated circuit comprising an input terminal and an output terminal and for fixed input and output impedances, a measurement method comprises applying to the input terminal a signal having a frequency spectrum comprising two lines at close frequencies, measuring the signal at the output terminal, and determining the variation of the transmission gain according to the input signal amplitude for one of the initial frequencies and for some of the intermodulation and harmonics frequencies due to the circuit non-linearities. The non-linear behavior quantification parameters may be measured from these curves.

A disadvantage is that the measurement of the curves of variation of the output power of an integrated circuit according to the input power requires complex tools, with an implementation which may be incompatible, for reasons of cost and delay, with the constraints encountered at an industrial scale by integrated circuit manufacturers.

There thus is a need for an integrated circuit testing method which enables to rapidly determine at least one parameter (for example, 1-dB intercept point IP1 or intercept point IP3) of quantification of the non-linear behavior of the integrated circuit in the absence of complex models of at least one electronic component of the integrated circuit and without performing large-signal measurements on the integrated circuit.

### SUMMARY OF THE INVENTION

An embodiment provides an integrated circuit testing method avoiding at least some of the disadvantages of prior test methods.

Another embodiment provides a simple test method, which can be implemented at low cost.

Another embodiment provides a test method which can be implemented for the same devices as those conventionally used to determine complex electronic component models.

For this purpose, an embodiment provides a method for testing an integrated circuit wherein at least first and second derivatives of S parameters of the integrated circuit are taken into account.

According to an embodiment, the method includes providing S parameters of the integrated circuit. An equivalent non-linear model of the integrated circuit is determined from the provided S parameters and first and second derivatives of the provided S parameters. The non-linear behavior of the integrated circuit is quantified from the equivalent non-linear model.

According to an embodiment, the step of provision of the S parameters comprises measuring the S parameters of the integrated circuit with a measurement device connected to the integrated circuit.

According to an embodiment, voltages and/or currents are applied to the integrated circuit in operation and the first and second derivatives of the provided S parameters are determined with respect to the voltages and/or to the currents.

According to an embodiment, the S parameters are measured for several bias points of the integrated circuit, and the first and second derivatives of the measured S parameters are determined for one of the bias points.

According to an embodiment, a method comprises determining an equivalent linear model comprising electronic components having their values only obtained from the provided S parameters. The equivalent non-linear model is determined by assigning to at least one of the electronic components 2nd and 3rd order non-linear coefficients based on the first and second derivatives of the provided S parameters.

According to an embodiment, the integrated circuit comprises a number N of ports, N being an integer greater than or equal to 2, each port being applied a signal at a reference value for the measurement of the S parameters, and the first and second derivatives of the provided S parameters comprise the first and second partial derivatives with respect to each signal, determined at the reference values.

According to an embodiment, the simulation step comprises applying a harmonic balance method to the equivalent non-linear model.

According to an embodiment, the method comprises manufacturing the integrated circuit and testing the integrated circuit manufactured by the previously-defined testing method.

According to an embodiment, the test step is followed by the manufacturing of a version of the integrated circuit modified according to the result of the test.

To achieve this, an embodiment provides a system for testing an integrated circuit capable of implementing the previously-defined testing method, comprising a device for providing the S parameters of the integrated circuit and a device for simulating the behavior of the integrated circuit based on the equivalent non-linear model of the integrated circuit.

According to an embodiment, the device comprises a device for measuring the S parameters of the integrated circuit.

The foregoing and other features and advantages will be discussed in detail in the following non-limiting description of specific embodiments in connection with the accompanying drawings.

### BRIEF DESCRIPTION OF THE DRAWINGS

FIG. 1 schematically shows an embodiment of an integrated circuit testing system;

FIG. 2 shows, in the form of a block diagram, an embodiment of an integrated circuit testing method;

FIGS. 3 and 4 schematically show embodiments of non-linear models of a MOS transistor; and

FIG. 5 shows curves of the variation of the output power for specific frequency lines according to the input power, respectively obtained by simulation from the model of FIG. 3 and by measurements on the integrated circuit.

### DETAILED DESCRIPTION OF ILLUSTRATIVE EMBODIMENTS

For clarity, the same elements have been designated with the same reference numerals in the different drawings.

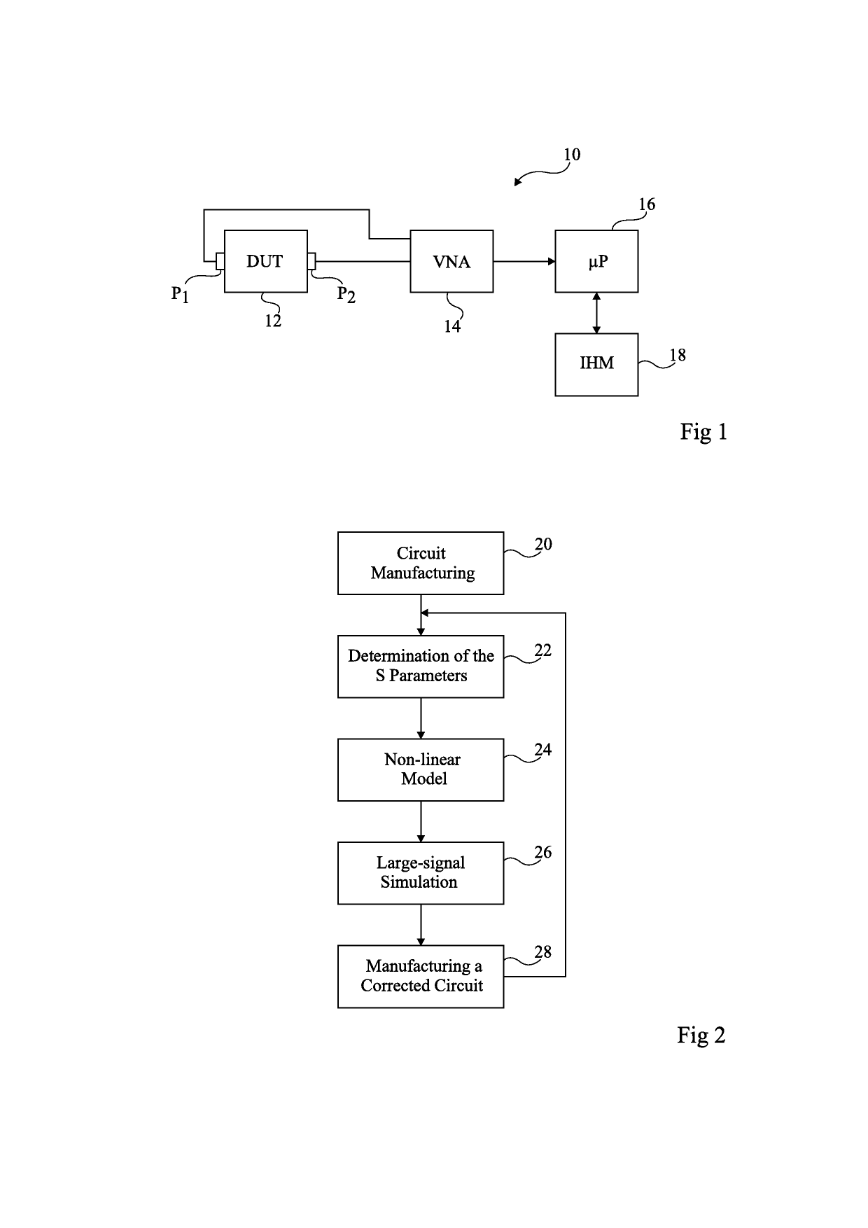

FIG. 1 shows an embodiment of a system 10 for testing an integrated circuit 12 (DUT or device under test). Integrated circuit 12 may comprise several electronic components, for example, bipolar transistors, MOS transistors, resistors, capacitors, inductances, amplifiers, attenuators, filters, couplers, equalizers, etc. It may however also correspond to a single electronic component, for example, a MOS transistor or a bipolar transistor. Integrated circuit 12 comprises from 1 to N ports, where N is a natural number greater than or equal to 2. The ports are the nodes of integrated circuit 12 at which electric currents flow into integrated circuit 12 or flow out of integrated circuit 12. In the embodiment of FIG. 1, integrated circuit 12 comprises two access ports P1, P2.

Testing system 10 comprises a device 14 (VNA) for measuring the Scattering parameters S, also called diffraction or distribution coefficients, of integrated circuit 12. Measurement device 14 is coupled to ports P1 and P2 of integrated circuit 12. Measurement device 14 may be a network analyzer 14, for example, a vectorial network analyzer. It may be the network analyzer sold under trade name VNA N5230A by Agilent Technologies.

Test system 10 further comprises a processing unit 16 (μP), for example, comprising a processor, receiving data provided by measurement device 14. Processing unit 16 is connected to an interface 18 (IHM), for example, comprising a display and a data entry system, for example, comprising a keyboard and a mouse. As a variation, measurement device 14 and processing unit 16 may be partly or totally confounded. Further, measurement device 14 may be connected to an interface for example comprising a display and a data entry system, for example, comprising a keyboard and a mouse. The processing unit 16 can further include a non-transitory memory to store program code operating on the processor, e.g., program code to perform the function described herein.

FIG. 2 schematically shows an embodiment of a method for testing integrated circuit 12 of FIG. 1. The system successively comprises:

a step 20 of integrated circuit manufacturing;

a step 22 of determination of the S parameters of integrated circuit 12 for several bias points;

a step 24 of determination of a non-linear model of operation of integrated circuit 12 based on the S parameters and on the first and second partial derivative (of 1st and 2nd orders) of the S parameters;

a step 26 of digital simulation of the non-linear operation model to determine the large-signal behavior of the integrated circuit; and

a possible step 28 of manufacturing of a corrected integrated circuit manufacturing, if necessary.

The inventors have shown that the use of the first partial derivatives of the S parameters enables satisfactory estimation of 2nd-order non-linear effects (for example, the appearing in the output signal spectrum of lines at the 2nd order harmonics and at the 2nd order intermodulation frequencies) which occur during the operation of integrated circuit 12, and that the use of the first and second partial derivatives of the S parameters enables to satisfactorily estimate 3rd-order non-linear effects (for example, the appearing in the output signal spectrum of lines at the 3rd order harmonics and at the 3rd order intermodulation frequencies) which occur during the operation of integrated circuit 12.

The example of embodiment will be described generally and, for illustration purposes, more precisely in the specific example where integrated circuit 12 is a MOS transistor.

At step 22, the S parameters of integrated circuit 12 are measured. Generally, the S parameters are used to describe the electric behavior of linear electric circuits according to the input signals.

A definition of S parameters can be found in “Composants, dispositifs et circuits actifs en micro-ondes” by P. F. Combes, J. Graffeuil, and J. F. Sautereau (Dunod, Paris, 1985, pages 123-125).

S parameters may be arranged in the form of an array. The array of parameters S describing an integrated circuit 12 comprising N ports comprises N² elements, each element corresponding to a complex number. To measure the S parameters, the operating conditions of integrated circuit 12 must be previously set, and in particular the impedances applied to the ports, generally 50 Ω, the operating temperature of integrated circuit 12, and the bias point of integrated circuit 12, especially the constant components of the voltages applied to the ports of integrated circuit 12, etc.

Each port of integrated circuit 12 is assigned an integer n which varies from 1 to N, where N is the total number of ports. Call aₙ and bₙ, respectively, the incident and reflected waves at port n. Further, call A and B, respectively, the incident wave and reflected wave vectors defined according to the following relations (1):

$$B = ( \begin{matrix}{b}_{1} \\ ⋮ \\ {b}_{N}\end{matrix} ) \\ A = ( \begin{matrix}{a}_{1} \\ ⋮ \\ {a}_{N}\end{matrix} ) \qquad ( 1 )$$

The S parameters link the incident waves to the waves reflected by the ports of integrated circuit 2. For an N-port integrated circuit, the S parameters may be arranged in an array according to the following relation (2):

$$B = SA = ( \begin{matrix}{b}_{1} \\ ⋮ \\ {b}_{N}\end{matrix} ) = ( \begin{matrix}{S}_{1 , 1} & … & {S}_{1 , N} \\ ⋮ & ⋱ & ⋮ \\ {S}_{N , 1} & … & {S}_{N , N}\end{matrix} ) ( \begin{matrix}{a}_{1} \\ ⋮ \\ {a}_{N}\end{matrix} ) \qquad ( 2 )$$

An element Si,j of array S, i and j each being an integer varying from 1 to N, may be determined by the following relation (3):

$${S}_{i , j} = \frac{{b}_{i , j}}{{a}_{i , j}} {\vert}_{{a}_{k} = 0 pour k \neq i} \qquad ( 3 )$$

In the embodiment shown in FIG. 1, integrated circuit 12 has two ports P1 and P2. The array of S parameters of integrated circuit 12 has the general shape provided by the following relation (4):

$$S = ( \begin{matrix}{S}_{1 , 1} & {S}_{1 , 2} \\ {S}_{2 , 1} & {S}_{2 , 2}\end{matrix} ) \qquad ( 4 )$$

Further, in the specific example where integrated circuit 12 is a MOS transistor, port P1 for example corresponds to the gate of the MOS transistor and port P2 corresponds to the drain of the MOS transistor.

At step 22, the S parameters are measured for several bias points of integrated circuit 12. More specifically, the S parameters are measured for a reference bias point and for bias points close to the reference bias point.

The biasing of an integrated circuit generally comprises setting the constant voltages powering the integrated circuit and setting the D.C. component of each variable voltage and/or current applied on the integrated circuit ports. The reference bias point then corresponds to first values of the constant voltages and of the D.C. components of the variable voltages applied to the integrated circuit, and each bias point close to the reference bias point is obtained by modifying the D.C. component of a single variable voltage or of a single variable current without modifying the D.C. components of the other voltages/currents. The Si,j parameters measured for each bias point are provided to processing unit 16.

In the specific example where integrated circuit 12 is a MOS transistor manufactured in a semiconductor substrate and assembled with a common source, the determination of the reference bias point of the MOS transistor comprises determining the constant voltage applied to the source of the MOS transistor, of the constant voltage applied to the substrate, of constant component VGS applied between the gate and the source of the MOS transistor, and of constant component VDS applied between the drain and the source of the MOS transistor. Each bias point close to the reference bias point is obtained by varying the D.C. component of voltage VGS or VDS, the other voltages remaining unmodified. As an example, the reference bias point corresponds to a gate-source voltage having a D.C. component higher than the threshold voltage of the MOS transistor and a drain-source voltage having a D.C. component of several hundred millivolts.

At step 24, processing unit 16 determines an equivalent non-linear model of integrated circuit 12. The determination of the equivalent non-linear model of integrated circuit 12 may be implemented by processing unit 16 by using the software sold under trade name Advanced Design System (ADS) by Agilent Technologies. As a variation, the equivalent non-linear model may be at least partly determined by measurement device 14.

A non-linear model comprising a small number of parameters is selected. A non-linear model of integrated circuit 12 corresponds to an electronic circuit having its operation reproducing, with a variable accuracy, the operation of integrated circuit 12 in digital simulations. The non-linear model comprises electronic components, and especially resistors, capacitors, current sources, voltage sources, inductances, etc. The model is called non-linear since some electronic components are considered as non-linear components, especially capacitors and current or voltage sources.

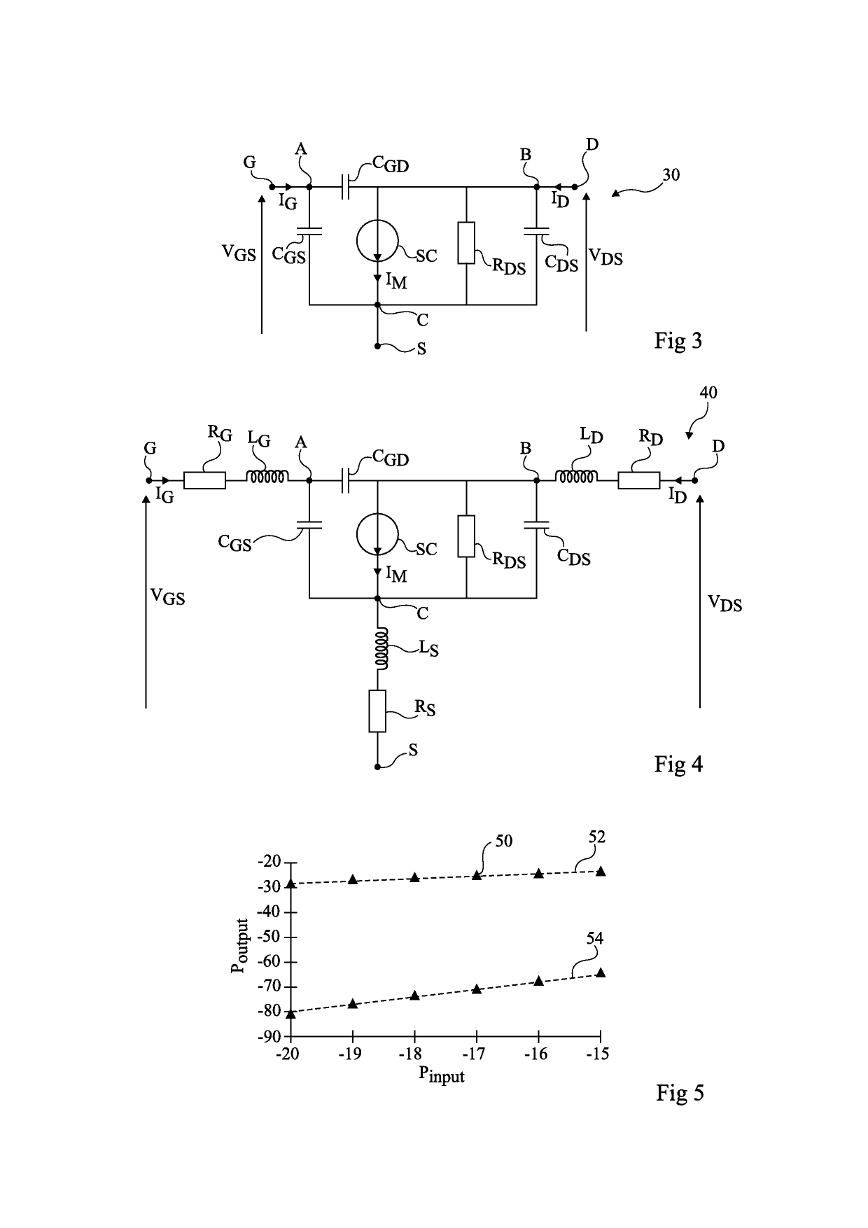

FIG. 3 shows an example of an equivalent non-linear MOS transistor model. The equivalent non-linear model may be implemented by the software sold under trade name Advanced Design System (ADS) by Agilent Technologies. In this example, the MOS transistor is modeled by a circuit 30 comprising three terminals G, S, and D respectively corresponding to the transistor gate, source, and drain. The following notations will be used:

VGS is the voltage between the gate and the source, and comprises the sum of a D.C. component VGS0 and of a variable component vGS;

VDS is the voltage between the drain and the source, and comprises the sum of a D.C. component VDS0 and of a variable component vDS;

IG is the input current at node G, and comprises the sum of a D.C. component IG0 and of a variable component iG which are zero for the MOS transistor; and

ID is the input current at node D, and comprises the sum of a D.C. component ID0 and of a variable component iD.

In the following description, reference is indifferently made to an electronic component (for example, a capacitor) and to the main property (the capacitance) of this electronic component.

Circuit 30 comprises:

a node A coupled to terminal G;

a node B coupled to terminal D;

a node C coupled to terminal S;

a capacitor CGS arranged between terminals A and C;

a capacitor CDS arranged between terminals B and C;

a capacitor CGD arranged between terminals A and B;

a resistor RDS arranged between terminals B and C in parallel with capacitor CDS; and

a voltage-controlled current source SC, arranged between terminals B and C, in parallel with capacitor CDS, providing a current IM equal to the product of voltage vGS by a gain GM.

FIG. 4 shows another example of a non-linear MOS transistor model. In this example, the MOS transistor is modeled by a circuit 40 comprising all the elements of circuit 30, and further comprising:

a resistor RG in series with an inductance LG between terminals G and A;

a resistor RD in series with an inductance LD between terminals D and B; and

a resistor RS in series with an inductance LS between terminals S and C.

First, processing unit 16 considers that each electronic component of the equivalent model is a linear component. Processing unit 16 then determines the expression of each electronic component according to the S parameters. As a variation, processing unit 16 may determine the expression of each electronic component based on the Y admittance parameters, on the Z impedance parameters, on the H hybrid parameters, on the T transfer parameters, or on ABCD parameters, which can all the deduced from the S parameters.

As an example, it is considered that the model of integrated circuit 12 is the model shown in FIG. 3, that the MOS transistor is biased with a common source, and that variable component vGS is a sinusoidal voltage of frequency f. The admittance parameters of integrated circuit 12 are provided by the following relation (5):

IG=Y11VGS+Y12VDS

ID=Y21VGS+Y22VDS (5)

In known fashion, parameters Y11, Y12, Y21, and Y22 may be expressed according to the S parameters.

The linear portions of the electronic components of the model are provided by the following relations (6):

GM=Re{Y21}

GDS=1/RDS=Re{(Y22+Y12)}

CDS=Im{(Y22+Y12)/(2πf)}

CDS=Im{(Y22+Y12)/(2πf)}

CDS=Im{(Y22+Y12)/(2πf)} (6)

where Re{U} and Im{U} respectively are the real part and the imaginary part of complex number U.

The non-linear model is obtained by using Taylor's series for each non-linear component. As an example, the expression of gain GM is given by the following relation (7), neglecting the crossed partial derivatives:

$${G}_{M} \approx {G}_{M 0} + \frac{\partial {G}_{M}}{\partial {V}_{GS}} {V}_{GS} + \frac{1}{2 !} \frac{{\partial }^{2} {G}_{M}}{\partial {V}_{GS}^{2}} {v}_{GS}^{2} + \frac{\partial {G}_{M}}{\partial {V}_{DS}} {v}_{DS} + \frac{1}{2 !} \frac{{\partial }^{2} {G}_{M}}{\partial {V}_{DS}^{2}} {v}_{DS}^{2} \qquad ( 7 )$$

Other approximations may be performed, for example, by considering that gain GM essentially depends on voltage VGS and that GDS essentially depends on voltage VDS.

For each electronic component, the term with index 0 corresponds to the linear term provided by relations (6). The terms comprising voltage vGS or voltage vDS correspond to the 2nd order non-linear terms and the terms comprising voltage vGS2 or voltage vDS2 correspond to the 3rd order non-linear terms. The 2nd-order linear terms of the electronic components of the equivalent model cause 2nd-order non-linear effects in the integrated circuit simulation with the equivalent model, especially the forming of 2nd-order harmonics and of 2nd-order intermodulations. The 2nd-order and 3rd-order non-linear terms of the electronic components of the equivalent model cause 3rd-order non-linear effects in the simulation of the integrated circuit with the equivalent model, especially the forming of 3rd-order harmonics and of 3rd-order intermodulations.

Processing unit 16 determines the non-linear terms for each non-linear electronic component of the equivalent model of integrated circuit 12. For this purpose, processing unit 16 determines, for each non-linear electronic component, the first and second partial derivatives of the linear term of the expression of the electronic component with respect to each D.C. voltage or current applied to a port of the integrated circuit.

In the specific example of the model shown in FIG. 3, the non-linear components are capacitances CGS, CGD, and CDS, output resistance RDS, and gain GM. One then determines: first partial derivatives ∂G_{M}/∂v_{GS}, ∂G_{M}/∂v_{DS}, ∂G_{DS}/∂v_{GS}, ∂G_{DS}/∂v_{DS}, ∂C_{GS}/∂v_{GS}, ∂C_{GS}/∂v_{DS}, ∂C_{GD}/∂v_{GS}, ∂C_{GD}/∂v_{DS}, ∂C_{DS}/∂v_{GS}, and ∂C_{DS}/∂v_{DS}; and second partial derivatives ∂²G_{M}/∂v_{GS}², ∂²G_{M}/∂v_{DS}², ∂²G_{DS}/∂v_{GS}², ∂²G_{DS}/∂v_{DS}², ∂²C_{GS}/∂v_{GS}², ∂²C_{GS}/∂v_{DS}², ∂²C_{GD}/∂v_{GS}², ∂²C_{GD}/∂v_{DS}², ∂²C_{DS}/∂v_{GS}², and ∂²C_{DS}/∂v_{DS}².

The previous values are determined at the reference bias point of integrated circuit 12.

The previous derivatives are obtained from the derivatives of the S parameters measured at different bias points.

As an example, when the reference bias point corresponds to a 440-mV gate-source voltage VGS0 and a 900-mV drain-source voltage VDS0, S parameters are determined for the bias points obtained by varying voltage VDS0 between 899.4 mV and 900.6 mV without modifying VGS0. These S parameters are used to determine partial derivatives ∂G_{M}/∂v_{DS} and ∂²G_{M}/∂v_{DS}² at the reference bias point.

Other S parameters are determined for the bias points obtained by varying voltage VGS0 between 439.4 mV and 440.6 mV without modifying VDS0. These S parameters are used to determine partial derivatives ∂G_{M}/∂v_{GS} and ∂²G_{M}/∂v_{GS}² at the reference bias point.

At step 24, the equivalent non-linear model to be used may be more or less complicated according to the type of integrated circuit 12 to be depicted by the equivalent non-linear model. The first time an equivalent non-linear model is selected to simulate the behavior of an integrated circuit, it may be desirable to provide a validation step to confirm that the selected equivalent non-linear model will enable to simulate the behavior of integrated circuit 12 with a sufficient accuracy. The validation step may be carried out by comparing simulations obtained with the equivalent non-linear model of the integrated circuit with measurements directly performed on the integrated circuit. The measurements are for example performed by the “Load-Pull” method. Afterwards, it is no longer necessary to provide this validation step when the equivalent non-linear model is used to simulate the behavior of an integrated circuit similar to that used for the validation.

As a variation, at step 24, the S parameters and the first and second derivatives of the S parameters may be determined from a complex model of integrated circuit 12 when said circuit is available, for example, a model from the BSIM or PSP family. In this case, step 22 of measurement of the S parameters at the reference bias point and at different bias points around the reference bias point may be omitted. Further, 3rd-order or higher-order derivatives of the S parameters may be determined.

At step 26, the method comprises the digital simulation of integrated circuit 12 from the non-linear equivalent model of integrated circuit 12 to quantify the non-linearity phenomena which occur during the operation of integrated circuit 12. The simulation may be implemented by conventional digital simulation methods. A digital simulation method implementing a harmonic balance may be used. An example of harmonic balance method is described in Chapter 3 of “Non linear microwave and RF circuits” by Stephen A. Maas (Artech House publishers, 2003). The digital simulation may be implemented by using the software sold under trade name Advanced Design System (ADS) by Agilent Technologies. Another example of a digital simulation method is a “transient”-type simulation method.

The harmonic balance method especially enables to determine parameters for quantifying the non-linear behavior, for example, gain compression points IP1 and IP3. At step 26, the non-linear behavior quantification parameters may be compared with reference values to determine whether the non-linear effects which would occur during the operation of integrated circuit 12 are compatible with the planned use of integrated circuit 12. As an example, it may be desirable for gain compression points IP1 and IP3 to be higher than reference values. When it is determined that the large-signal behavior of integrated circuit 12 is satisfactory, the test method may stop after step 26. When it is determined that the large-signal behavior of integrated circuit 12 is not satisfactory, the test method may carry on at step 28.

Further, other simulations than large-signal behavior simulations may be performed, possibly by adapting the equivalent non-linear model with respect to what has been previously described. As an example, the equivalent non-linear model may be adapted to be used to simulate the operation of integrated circuit 12 when it receives noisy signals. Further, at step 26, when the 3rd and/or higher-order derivatives of the S parameters have been determined at step 24, the simulation may enable to determine 4th-order and/or higher-order parameters for quantifying non-linear effects.

At step 28, integrated circuit 12 is modified. This may mean at least one of the following possibilities:
the structure of at least one electronic component of integrated circuit 12 may be modified. For example, when the electronic component is a MOS transistor, the shape of the gate may be modified;
the electric circuit corresponding to the integrated circuit may be modified by addition or removal of electronic components; and/or
the integrated circuit manufacturing method may be modified. For example, when the method comprises photolithography steps, the nature of the etch products used may be modified. When the method comprises thermal anneal steps, the anneal time or temperature may be modified.

At step 28, a modified integrated circuit 12 is manufactured. The method can then be repeated from step 22 to determine the non-linear behavior quantification parameters of the modified integrated circuit to define to what extent the behavior of modified integrated circuit 12 has improved.

Comparison tests have been carried out to validate the relevance of the previously-described equivalent non-linear model. Tests have been carried out by comparing simulations obtained with the equivalent non-linear model for an NMOS transistor, assembled with a common source, made in a technology for which the channel length is 32 nm and with respect to measurements directly performed on the transistor. The measurements have been performed by a system for implementing the “Load-Pull” method. The “Load-Pull” method is, for example, described in “Etude d'amplificateurs faible niveau à haute linéarité en technologies intégrées HEMT AsGa pour applications spatiales” by Joseph Taphuh Mouaof (Limoges University, year 2008, Thesis n°81-2008, pages 164-165. Variable signal vGS applied to the transistor gate comprises a line at a 2-GHz frequency and a line at a 2.05-GHz frequency. The NMOS transistor has been biased to a 440-mV gate-source voltage VGS0 and to a 900-mV drain-source voltage VDS0.

FIG. 5 shows curves of the variation of the output power (Poutput) versus the applied input power (Pinput). Triangles 50 are the results of the simulations of the previously-described equivalent non-linear model. Curves 52 and 54 in dotted lines correspond to the measurements by the “Load-Pull” method.

Curve 52 corresponds to the output power associated with the fundamental 2-GHz line and curve 54 corresponds to the output power associated with the 3rd-order 1.95-GHz intermodulation line. Point IP3 has been determined. Measurements according to the “Load-Pull” method provide a 6.65-dBm point IP3 while the simulation using the previously-described equivalent non-linear model provides a 7.15-dBm point IP3. Values 50 obtained by simulation by using the previously-described equivalent non-linear model are effectively in accordance with the values measured by the “Load-Pull” method. The deviations between measurement curves 52 and 54 and simulations (triangles 50) are smaller than 0.3 dB.

The previously-described equivalent non-linear model can thus be used for simulations, even at impedances different from the impedances used to measure the S parameters. Thus, by deducing an equivalent non-linear model by means of measurements of the S parameters under 50 ohms, an equivalent non-linear model having a behavior valid for any source and charge impedance is obtained.

Specific embodiments of the present invention have been described. Various alterations and modifications will occur to those skilled in the art. In particular, the S parameters are determined for a measurement temperature. The non-linear operation model determined according to the present embodiment is adapted for the measurement temperature. If a simulation must be performed at a temperature different from the measurement temperature, then the S parameters are measured at this new temperature to determine a non-linear behavior model at this new temperature.

An advantage of the previously-described embodiments of the integrated circuit testing method is that it enables to determine parameters of quantification of the non-linear behavior of the integrated circuit, that is, of the large-signal behavior of the integrated circuit, by means of the S parameters which are measured for small signals.

Another advantage of the previously-described embodiments of the integrated circuit testing method is that it enables to follow the variation of the non-linear behavior of an integrated circuit according to the variation of the integrated circuit manufacturing method.

Another advantage of the previously-described embodiments of the integrated circuit testing method is that it enables to simulate the behavior of an integrated circuit at frequencies greater than the frequency of the input signal applied to the integrated circuit. Indeed, the simulation of the non-linear effects, and more specifically of 2nd-order and 3rd-order harmonics, reflects the integrated circuit behavior at frequencies equal to 2 and 3 times the fundamental frequency of the input signal.

Another advantage of the previously-described embodiments of the integrated circuit testing method is that it enables to decrease the time taken by the simulations of the behavior of an integrated circuit. Indeed, the equivalent non-linear model of an integrated circuit such as described previously implemented in the testing method is simpler than a complex model of this same integrated circuit, for example, a complex model from the PSP or BSIM family. Thereby, a simulation using the equivalent non-linear model of the integrated circuit is faster than a simulation directly implementing the complex model of this integrated circuit.

Such alterations, modifications, and improvements are intended to be part of this disclosure, and are intended to be within the spirit and the scope of the present invention. Accordingly, the foregoing description is by way of example only and is not intended to be limiting. The present invention is limited only as defined in the following claims and the equivalents thereto.

What is claimed is:

1. A method for testing an integrated circuit, the method comprising:
determining performance data of the integrated circuit, wherein at least first and second derivatives of S parameters of the integrated circuit are taken into account when determining the expected performance data;
wherein the determining is performed using a processing unit that includes a processor.

2. The method of claim 1, wherein determining the performance data comprises:
providing S parameters of the integrated circuit;
determining an equivalent non-linear model of the integrated circuit from the provided S parameters and first and second derivatives of the provided S parameters; and
quantifying the non-linear behavior of the integrated circuit from the equivalent non-linear model.

3. The method of claim 2, wherein providing the S parameters comprises measuring the S parameters of the integrated circuit with a measurement device connected to the integrated circuit.

4. The method of claim 2, wherein determining the performance data comprises applying a harmonic balance method to the equivalent non-linear model.

5. The method of claim 1, wherein determining the performance data comprises applying voltages and/or currents to the integrated circuit in operation and wherein the first and second derivatives of the provided S parameters are determined with respect to the voltages and/or to the currents.

6. The test method of claim 1, wherein the S parameters are measured for several bias points of the integrated circuit, and wherein the first and second derivatives of the measured S parameters are determined for one of the bias points.

7. The method of claim 1, further comprising:
determining an equivalent linear model comprising electronic components having their values only obtained from the provided S parameters; and
determining the equivalent non-linear model by assigning at least one of the electronic components with 2nd or 3rd order non-linear coefficients based on the first and second derivatives of the provided S parameters.

8. The method of claim 1, wherein the integrated circuit comprises a number N of ports, N being an integer greater than or equal to 2, each port being applied a signal at a reference value for the measurement of the S parameters, and wherein the first and second derivatives of the provided S parameters comprise the first and second partial derivatives with respect to each signal, determined at the reference values.

9. A method for manufacturing an integrated circuit, the method comprising:
manufacturing the integrated circuit; and
testing the integrated circuit using the testing method of claim 1.

10. The method of claim 9, further comprising manufacturing a second integrated circuit that has modified according to a result of the testing.

11. A method for testing an integrated circuit, the method comprising:
providing S parameters of the integrated circuit;
determining an equivalent non-linear model of the integrated circuit from the provided S parameters and first and second derivatives of the provided S parameters; and
quantifying the non-linear behavior of the integrated circuit from the equivalent non-linear model, wherein the quantifying is performed using a processing unit that includes a processor.

12. The method of claim 11, wherein providing the S parameters comprises measuring the S parameters of the integrated circuit with a measurement device connected to the integrated circuit.

13. The method of claim 12, wherein providing the S parameters comprises applying voltages and/or currents to the integrated circuit in operation and wherein the first and second derivatives of the provided S parameters are determined with respect to the voltages and/or to the currents.

14. The method of claim 12, wherein measuring the S parameters comprises measuring the S parameters for several bias points of the integrated circuit.

15. The method of claim 14, wherein the first and second derivatives of the measured S parameters are determined for one of the bias points.

16. The method of claim 12, wherein the integrated circuit comprises a number N of ports, N being an integer greater than or equal to 2, each port being applied a signal at a reference value for the measurement of the S parameters, and wherein the first and second derivatives of the provided S parameters comprise the first and second partial derivatives with respect to each signal, determined at the reference values.

17. The method of claim 12, wherein method includes applying a harmonic balance method to the equivalent non-linear model.

18. The method of claim 11, further comprising determining an equivalent linear model comprising electronic components having their values only obtained from the provided S parameters;
wherein determining the equivalent non-linear model comprises assigning at least one of the electronic components with 2nd or 3rd order non-linear coefficients based on the first and second derivatives of the provided S parameters.

19. A method for manufacturing an integrated circuit, the method comprising:
manufacturing the integrated circuit; and
testing the integrated circuit using the testing method of claim 11.

20. The method of claim 19, further comprising manufacturing a second integrated circuit that has modified according to a result of the testing.

21. A test system comprising:
a measuring device configured to measure capable S parameters of an integrated circuit; and
a processing device configured to simulate behavior of the integrated circuit based on an equivalent non-linear model of the integrated circuit, wherein first and second derivatives of S parameters of the integrated circuit are taken into account when simulating the behavior.

22. The test system of claim 21, wherein the processing device is configured to determine the equivalent non-linear model of the integrated circuit from the S parameters and the first and second derivatives of the provided S parameters.

23. The test system of claim 22, wherein the processing device is further configured to quantify the non-linear behavior of the integrated circuit from the equivalent non-linear model.

24. The test system of claim 21, wherein the measuring device comprises a network analyzer.

25. The test system of claim 21, wherein the processing device comprises a microprocessor.

26. The test system of claim 25, wherein the processing device further comprises a memory configured to store program code for operation of the microprocessor.

27. A system for testing an integrated circuit, the system comprising:
a microprocessor, wherein the microprocessor is to evaluate the integrated circuit by:
receiving S parameters of the integrated circuit;
determining an equivalent non-linear model of the integrated circuit from the provided S parameters and first and second derivatives of the provided S parameters; and
quantifying the non-linear behavior of the integrated circuit from the equivalent non-linear model, wherein the quantifying is performed using a processing unit that includes a processor.

28. The testing system of claim 27, further comprising a device for measuring the S parameters of the integrated circuit.
